(19) United States
(12) Patent Application Publication
(10) Pub. No.: US 2026/0282437 A1
(43) Pub. Date: Sep. 17, 2026

(54) SEMICONDUCTOR DEVICE

(71) Applicants: Kabushiki Kaisha Toshiba, Kawasaki-shi (JP); Toshiba Electronic Devices & Storage Corporation, Kawasaki-shi (JP)

(72) Inventors: Hiroaki KATOU, Nonoichi Ishikawa (JP); Tsuyoshi KACHI, Kanazawa Ishikawa (JP)

(21) Appl. No.: 19/310,262

(22) Filed: Aug. 26, 2025

(30) Foreign Application Priority Data
Mar. 12, 2025 (JP) 2025-039571

(51) Int. Cl. H10D 30/66; H10D 62/10; H10D 62/60; H10D 64/00; H10D 64/62

(52) U.S. Cl. CPC H10D 30/668; H10D 30/665; H10D 62/102; H10D 62/124; H10D 62/60; H10D 64/112; H10D 64/117; H10D 64/62

(57) ABSTRACT

According to embodiments, a semiconductor device comprises: a first electrode; a second electrode positioned above the first electrode; and a semiconductor layer positioned between the first electrode and the second electrode, including: a first semiconductor region of a first conductivity type; a second semiconductor region of a second conductivity type that is provided on the first semiconductor region and that is electrically connected to the second electrode; a third semiconductor region of the first conductivity type that is provided on the second semiconductor region; a fourth semiconductor region of the second conductivity type that is provided on the first semiconductor region and that is electrically connected to the second electrode; a plurality of third electrodes, wherein each of the plurality of third electrodes faces the first semiconductor region, with a plurality of first insulating portions between the plurality of third electrodes and the first semiconductor region; and a fourth electrode.

### CROSS-REFERENCE TO RELATED APPLICATION

This application is based upon and claims the benefit of priority from Japanese Patent Application No. 2025-039571, filed on Mar. 12, 2025; the entire contents of which are incorporated herein by reference.

### FIELD

Embodiments relate to a semiconductor device.

### BACKGROUND

There is a semiconductor device such as a MOSFET (Metal Oxide Semiconductor Field Effect Transistor) with a gate electrode formed in a trench.

### BRIEF DESCRIPTION OF THE DRAWINGS

FIG. 1 is a schematic plan view illustrating a semiconductor device according to embodiments.

FIG. 2 is a schematic diagram illustrating a semiconductor device according to embodiments.

FIG. 3 is a schematic cross-sectional view illustrating a semiconductor device according to embodiments.

FIG. 4 is another schematic cross-sectional view illustrating a semiconductor device according to embodiments.

### DETAILED DESCRIPTION

According to embodiments of the present invention, a semiconductor device comprises a first electrode, a second electrode, and a semiconductor layer. The second electrode is positioned above the first electrode in a first direction. The semiconductor layer is positioned in the first direction between the first electrode and the second electrode. The semiconductor layer includes a first semiconductor region of a first conductivity type, a second semiconductor region of a second conductivity type, a third semiconductor region of the first conductivity type, a fourth semiconductor region of the second conductivity type, a plurality of third electrodes, and a fourth electrode. The first semiconductor region is provided in both an inner area and an outer area of the semiconductor layer, wherein the outer area partially surrounds the inner area. The second semiconductor region is provided on the first semiconductor region in the inner area and is electrically connected to the second electrode. The third semiconductor region is provided on the second semiconductor region. The fourth semiconductor region is provided on the first semiconductor region in the outer area and is electrically connected to the second electrode. The plurality of third electrodes are provided in both the inner area and the outer area, wherein each of the plurality of third electrodes faces the first semiconductor region in a second direction perpendicular to the first direction, with a plurality of first insulating portions between the plurality of third electrodes and the first semiconductor region. The fourth electrode is provided in both the inner area and the outer area. The fourth electrode extends between two of the plurality of third electrodes that are adjacent in the second direction. In the inner area, the fourth electrode is separated from the plurality of third electrodes by the semiconductor layer and a first group of second insulating portions. In the inner area, the fourth electrode faces the first semiconductor region, the second semiconductor region, and the third semiconductor region in the second direction with the first group of second insulating portions between the fourth electrode and the first semiconductor region, the second semiconductor region, and the third semiconductor region. In the outer area, the fourth electrode is positioned above the fourth semiconductor region in the first direction with a second group of second insulating portions between the fourth electrode and the fourth semiconductor region.

Embodiments of the present invention will be described below with reference to the drawings. The drawings are schematic or conceptual, and the relationship between the thickness and width of each part, the size ratio between parts, etc., are not necessarily the same as the actual ones in practice. Even when illustrating the same part, the dimensions and ratios may differ depending on the drawing. In the present specification and each drawing, elements that have already been described are denoted by the same reference numerals, and detailed descriptions are appropriately omitted. In the following examples, a “first conductivity type” is n-type, and a “second conductivity type” is p-type. However, in each embodiment described below, the p-type and n-type of each semiconductor region may be reversed to implement each embodiment.

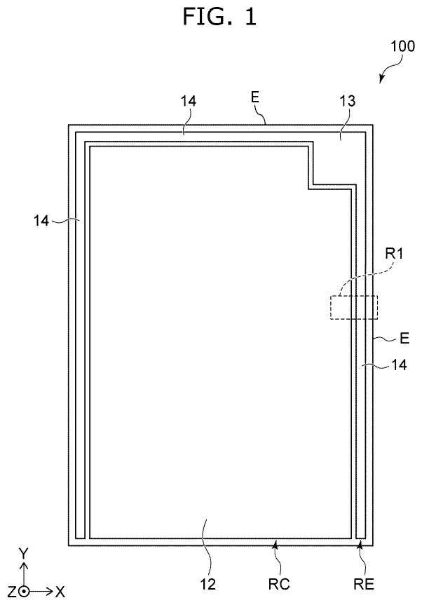

FIG. 1 is a schematic plan view illustrating a semiconductor device 100 according to embodiments. In the description of the embodiments, an X direction, a Y direction, and a Z direction, which are orthogonal to each other, are used. For example, as shown in FIG. 1, when viewed from above (viewed along the Z direction), the semiconductor device 100 according to the embodiments may have a rectangular shape with sides extending in the X and Y directions.

The semiconductor device 100 may be, for example, a MOSFET. On the upper surface side of the semiconductor device 100, a source electrode 12, a gate pad 13, and a gate wiring 14 are provided. The source electrode 12, the gate pad 13, and the gate wiring 14 may be arranged, for example, in the same X-Y plane.

The semiconductor device 100 is provided with an element region RC, sometimes referred to herein as an “inner area,” and a termination region RE located around the element region RC in the X-Y plane, sometimes referred to herein as an “outer area.” The element region RC is a region where a transistor is provided in a semiconductor layer 20 described later. The source electrode 12 extends in the X-Y plane and covers at least a part of the element region RC. The gate pad 13 and the gate wiring 14 may be arranged in the element region RC and outside the element region RC. The source electrode 12 is insulated from the gate pad 13 and the gate wiring 14.

The termination region RE is arranged alongside the element region RC within the X-Y plane. The termination region RE includes the outer edge (end E in the X direction or Y direction) of the semiconductor layer 20 and is a region along the outer edge. The termination region RE may partially surround the element region RC. The element region RC is located between the termination region RE and the center of the semiconductor layer 20.

The gate wiring 14 and the gate pad 13 may be, for example, arranged in the termination region RE and may surround the source electrode 12. The gate wiring 14 extends in the X direction or Y direction and is electrically connected to the gate pad 13. In the illustrated example, the gate pad 13 is arranged at the corner of the rectangle of the semiconductor device 100.

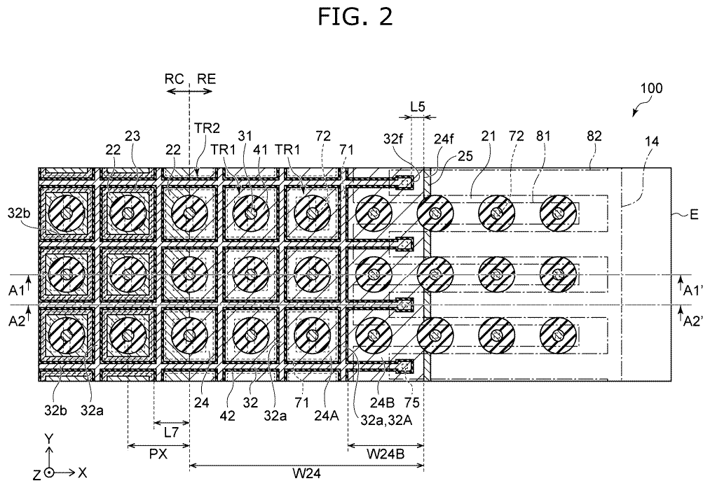

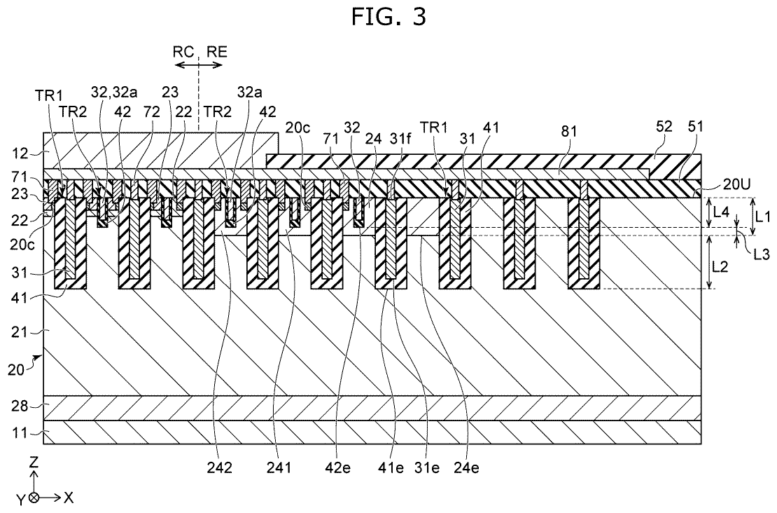

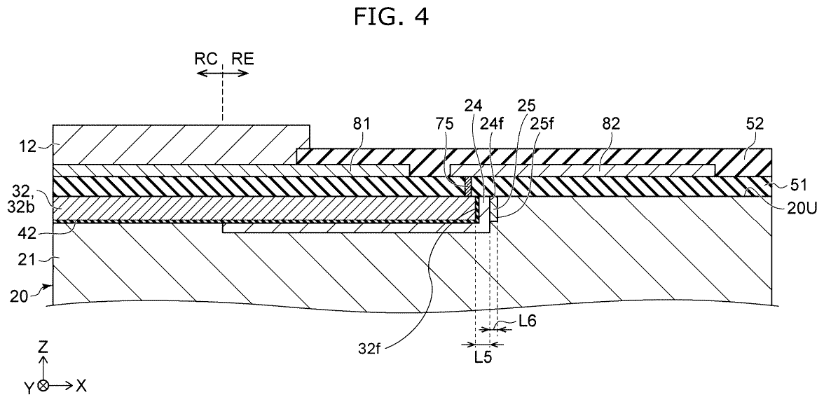

FIG. 2 is a schematic diagram illustrating the semiconductor device 100 according to the embodiments. FIG. 3 and FIG. 4 are schematic cross-sectional views illustrating the semiconductor device 100 according to the embodiments. FIG. 2 to FIG. 4 illustrate the structure of the semiconductor device 100 near the boundary between the element region RC and the termination region RE (region R1 shown in FIG. 1). FIG. 2 illustrates a part of the planar layout of the semiconductor device 100. FIG. 3 illustrates the cross-section along a line A1-A1′ shown in FIG. 2. FIG. 4 illustrates the cross-section along a line A2-A2′ shown in FIG. 2.

For example, as shown in FIG. 3, the semiconductor device 100 may include a drain electrode 11, the source electrode 12, and the semiconductor layer 20. The semiconductor layer 20 is positioned between the drain electrode 11 and the source electrode 12 in the Z direction.

In the description of the embodiments, the direction from the drain electrode 11 to the source electrode 12 is referred to as the Z direction. The upper and lower surfaces of the semiconductor layer 20 extend along the X-Y plane perpendicular to the Z direction. For convenience, the direction from the drain electrode 11 to the source electrode 12 is also referred to herein as “up,” and the opposite direction is referred to herein as “down.” These directions are based on the relative positional relationship between the drain electrode 11 and the source electrode 12 and are independent of the direction of gravity.

The semiconductor layer 20 includes a drain region 28, a drift region 21, a base region 22, and a source region 23.

The drain region 28 is provided in both the element region RC and the termination region RE. The drain region 28 is a semiconductor region of the first conductivity type. The drain region 28 is provided on the drain electrode 11 and is electrically connected to the drain electrode 11.

For example, the drift region 21 may be provided in both the element region RC and the termination region RE. The drift region 21 is a semiconductor region of the first conductivity type provided on the drain region 28. The concentration of n-type impurities (e.g., in atoms/cm³) in the drift region 21 is lower than the concentration of n-type impurities (e.g., in atoms/cm³) in the drain region 28. The drift region 21 is electrically connected to the drain electrode 11 via the drain region 28.

The base region 22 is provided on the drift region 21 in the element region RC. The base region 22 is a semiconductor region of the second conductivity type (p-type) provided on a part of the drift region 21. Multiple portions of the base region 22 are arranged in the X direction and Y direction. The base region 22 is electrically connected to the source electrode 12 via conductive contact portions 71, also referred to herein as “contacts,” and a wiring layer 81, that are in contact with, i.e., coupled to, the upper surface of the semiconductor layer 20.

The source region 23 is a semiconductor region of the first conductivity type provided on a part of the base region 22. The source region 23 is located on an upper surface 20U of the semiconductor layer 20 and is in contact with the contact portions 71. The source region 23 includes multiple portions. The source region 23 is electrically connected to the source electrode 12 via the contact portions 71. The concentration of n-type impurities (e.g., in atoms/cm³) in the source region 23 is higher than the concentration of n-type impurities in the drift region 21.

For example, the element region RC may be the range within the X-Y plane that includes the source region 23. For example, the termination region RE may be the range within the X-Y plane where the source region 23 is not provided.

The semiconductor layer 20 further includes a termination base region 24. The termination base region 24 is provided on the drift region 21 in the termination region RE. The termination base region 24 is a semiconductor region of the second conductivity type (p-type) provided on a part of the drift region 21 and forms a pn junction with the drift region 21. The termination base region 24 may be provided outside the element region RC. The termination base region 24 is electrically connected to the source electrode 12 via the contact portions 71 and the wiring layer 81. The termination base region 24 is deeper than the base region 22 in the down direction. That is, the lower end of the termination base region 24 is lower than the lower end of the base region 22.

The upper ends of the base region 22 and the termination base region 24 may be located on the upper surface 20U of the semiconductor layer 20. As shown in FIG. 3, a contact region 20c may be provided on each of the base region 22 and the termination base region 24. The contact region 20c is a semiconductor region of the second conductivity type (p-type). The contact region 20c has a higher concentration of impurities of the second conductivity type than each of the base region 22 and the termination base region 24. The contact region 20c is located on the upper surface 20U of the semiconductor layer 20 and is in contact with the contact portions 71. The base region 22 and the termination base region 24 are each electrically connected to the contact portions 71 via the contact region 20c.

As shown in FIG. 3, multiple FP trenches TR1 and gate trenches TR2 are provided on the upper surface 20U of the semiconductor layer 20.

Each FP trench TR1 extends down from the upper surface 20U to the drift region 21 in the Z direction. Each FP trench TR1 is provided with an FP insulating portion 41 and an FP electrode 31. Each FP insulating portion 41 covers the inner wall (side and bottom surfaces) of the respective FP trench TR1. The lower and side surfaces of each FP insulating portion 41 are in contact with the drift region 21.

Each FP electrode 31 may be, for example, a field plate. The FP electrode 31 is located inside the FP insulating portion 41 in the respective FP trench TR1. In other words, the FP insulating portion 41 is provided between the FP electrode 31 and the semiconductor layer 20. The lower and side surfaces of the FP electrode 31 are in contact with the respective FP insulating portion 41. The FP electrode 31 is insulated from the semiconductor layer 20 by the respective FP insulating portion 41.

Each FP insulating portion 41 provided in the element region RC is in contact with the drift region 21 and the base region 22. Each FP electrode 31 provided in the element region RC is arranged alongside a part of the drift region 21 and the base region 22 within the X-Y plane. That is, each FP electrode 31 provided in the element region RC faces a part of the drift region 21 and the base region 22 in the X direction and the Y direction, with a respective FP insulating portion 41 in between.

Each FP insulating portion 41 provided in the termination region RE is in contact with the drift region 21 and the termination base region 24. Each FP electrode 31 provided in the termination region RE is arranged alongside a part of the drift region 21 and the termination base region 24 within the X-Y plane. That is, each FP electrode 31 provided in the termination region RE faces a part of the drift region 21 and the termination base region 24 in the X direction and the Y direction, with a respective FP insulating portion 41 in between.

Each gate trench TR2 is located between two adjacent FP trenches TR1 (the closest FP trenches TR1 among the multiple FP trenches TR1). Each gate trench TR2 is shallower than the FP trenches TR1.

Each gate trench TR2 is provided with a gate insulating portion 42 and a gate electrode 32, including a group of gate insulating portions 42 in the element region RC and a group of gate insulating portions in the termination region RE. The gate insulating portion 42 covers the inner wall of the respective gate trench TR2.

The gate electrode 32 is located inside the gate trenches TR2, positioned within the respective gate insulating portions 42. In other words, each gate insulating portion 42 is provided between the gate electrode 32 and the semiconductor layer 20. In the element region RC and the termination region RE, the bottom and sides of the gate electrode 32 are in contact with the gate insulating portions 42. The gate electrode 32 is insulated from the semiconductor layer 20 by the gate insulating portions 42. Each FP electrode 31 extends to a deeper position than the gate electrode 32.

In the element region RC, each gate trench TR2 extends down in the Z direction from the upper surface 20U of the semiconductor layer 20 to the drift region 21. In the element region RC, each gate insulating portion 42 is in contact with the drift region 21, the base region 22, and the source region 23. In the element region RC, the gate electrode 32 is aligned in the X-Y plane with a part of the drift region 21, the base region 22, and a part of the source region 23. That is, in the element region RC, the gate electrode 32 faces the drift region 21, the base region 22, and the source region 23, with the gate insulating portions 42 in between.

In the termination region RE, each gate trench TR2 extends down in the Z direction from the upper surface 20U of the semiconductor layer 20 into the termination base region 24, but does not reach the drift region 21. In the termination region RE, the bottom and sides of each gate insulating portion 42 are covered and in contact with the termination base region 24. In the termination region RE, each gate insulating portion 42 does not contact the drift region 21. In the termination region RE, the lower end of each gate insulating portion 42 is in contact with the termination base region 24. In the termination region RE, the gate electrode 32 is located above a part of the termination base region 24. In the termination region RE, the gate electrode 32 is aligned in the X-Y plane with another part of the termination base region 24. That is, in the termination region RE, the gate electrode 32 faces the termination base region 24, with the gate insulating portions 42 in between.

In the element region RC, the different portions of the base region 22 are separated by the gate trenches TR2. On the other hand, in the termination region RE, the termination base region 24 extends continuously below the gate trenches TR2 and is not divided by the gate trenches TR2.

As shown in FIG. 3, an insulating layer 51 extending along the X-Y plane is provided on the upper surface 20U of the semiconductor layer 20. The insulating layer 51 is provided in contact with the upper surface 20U of the semiconductor layer 20, the upper surfaces of the FP insulating portions 41, and the upper surfaces of the gate insulating portions 42.

As shown in FIG. 3, in the element region RC and the termination region RE, a wiring layer 81 is provided on the insulating layer 51. A source electrode 12 is provided on the wiring layer 81.

Between the wiring layer 81 and the semiconductor layer 20, multiple contact portions 71 and 72 penetrating the insulating layer 51 are provided. The contact portions 71 are in contact with the upper surface 20U of the semiconductor layer 20 and the upper surfaces of the FP insulating portions 41. In the element region RC, each contact portion 71 is in contact with portions of the source region 23 and the base region 22 (via the contact region 20c described above). In the termination region RE, each contact portion 71 is in contact with the termination base region 24 (via the contact region 20c described above).

Each contact portion 72 is in contact with the upper surface of a respective FP electrode 31. Each FP electrode 31 is electrically connected to the source electrode 12 through the respective contact portion 72 and the wiring layer 81.

As shown in FIG. 4, in the termination region RE, a wiring layer 82 is provided on the insulating layer 51. The wiring layer 82 is connected to the gate wiring 14 described with respect to FIG. 1. The wiring layer 82 is insulated from the wiring layer 81 and the source electrode 12.

Between the wiring layer 82 and the gate electrode 32, a contact portion 75 penetrating the insulating layer 51 is provided. The contact portion 75 is in contact with the gate electrode 32 and the wiring layer 82. Thus, the gate electrode 32 is electrically connected to the gate pad 13 through the contact portion 75, the wiring layer 82, and the gate wiring 14.

As shown in FIG. 3 and FIG. 4, an insulating layer 52 may be provided. The insulating layer 52 is provided on the insulating layer 51, the wiring layer 81, and the wiring layer 82. The insulating layer 51 and the insulating layer 52 may each be a single layer or a laminated structure with multiple layers.

As shown in FIG. 2, the FP trenches TR1 and the FP electrodes 31 are arranged in the X direction with a first period, i.e., periodically at first intervals, and in the Y direction with a second period, i.e., periodically at second intervals. The first period and the second period may be the same or different from each other.

In the X-Y plane, each FP trench TR1 may be, for example, approximately circular. Each FP trench TR1 may also be polygonal. Each FP electrode 31 is columnar (for example, cylindrical) and extends in the Z direction.

As shown in FIG. 2, in the element region RC, each portion of the base region 22 is arranged to surround one FP trench TR1. Each portion of the source region 23 is provided along one of the gate trenches TR2 to surround a portion of the base region 22.

The termination base region 24 is provided continuously beginning at the end of the base region 22 (provided on the termination region RE side) and is provided to contact the outer peripheries of a plurality of the FP trenches TR1.

Each gate trench TR2 (including the gate electrode 32 and the respective gate insulating portion 42) is mesh-like or lattice-like in the X-Y plane, surrounding the FP trenches TR1, the base region 22, and the source region 23. In this example, the gate electrode 32 includes a plurality of first extending portions 32a extending in the Y direction and in the Z direction and a plurality of second extending portions 32b extending in the X direction. The gate electrode 32 is lattice-like with multiple first extending portions 32a and multiple second extending portions 32b intersecting.

More specifically, each first extending portion 32a extends in the Y direction, between two adjacent FP trenches TR1 in the X direction. Each first extending portion 32a is separated from two adjacent FP trenches TR1 in the X direction by the semiconductor layer 20 and the respective gate insulating portion 42. A plurality of first extending portions 32a are arranged in the X direction. The first extending portions 32a and the FP trenches TR1 are alternately arranged in the X direction.

Each first extending portion 32a provided in the element region RC faces the drift region 21, the base region 22, and the source region 23 in the X direction through a part of the respective gate insulating portion 42. Each first extending portion 32a provided in the termination region RE faces the termination base region 24 in the X direction through a part of the respective gate insulating portion 42. Further, each first extending portion 32a provided in the termination region RE is positioned above a part of the termination base region 24 with a part of the respective gate insulating portion 42 in between (see FIG. 3).

Each second extending portion 32b extends in the X direction, between two adjacent FP trenches TR1 in the Y direction. Each second extending portion 32b is separated from two adjacent FP trenches TR1 in the Y direction by the semiconductor layer 20 and the respective gate insulating portion 42. A plurality of second extending portions 32b are arranged in the Y direction. The second extending portions 32b and the FP trenches TR1 are alternately arranged in the Y direction.

Each second extending portion 32b provided in the element region RC faces the drift region 21, the base region 22, and the source region 23 in the Y direction, with a part of the respective gate insulating portion 42 in between. Each second extending portion 32b provided in the termination region RE faces the termination base region 24 in the Y direction, with a part of the respective gate insulating portion 42 in between. Further, each second extending portion 32b provided in the termination region RE is positioned above a part of the termination base region 24, with a part of the respective gate insulating portion 42 in between (see FIG. 4).

An example of the materials of each element of the semiconductor device 100 will be described. Each semiconductor region of the semiconductor layer 20 may include silicon (Si), silicon carbide, gallium nitride, or gallium arsenide as semiconductor materials. When silicon is used as the semiconductor material, arsenic, phosphorus, or antimony can be used as the n-type impurity. Boron can be used as the p-type impurity. The semiconductor layer 20 may be, for example, a semiconductor substrate such as a silicon substrate. The FP electrode 31 and the gate electrode 32 include conductive materials such as polysilicon or metal. The FP insulating portion 41, the gate insulating portion 42, the insulating layer 51, and the insulating layer 52 include insulating materials such as silicon oxide or silicon nitride. The drain electrode 11, the source electrode 12, the wiring layer 81, the wiring layer 82, the gate wiring 14, and the gate pad 13 include metal materials containing at least one of Al (aluminum) and Cu (copper). The contact portions 71 and the contact portions 75 include metal materials containing at least one selected from the group consisting of Ti (titanium), TiN (titanium nitride), W (tungsten), Cu, and Al.

The operation of the semiconductor device 100 will now be described. In a state where a positive voltage with respect to the potential of the source electrode 12 is applied to the drain electrode 11, a positive voltage is applied to the gate pad 13. As a result, a voltage is applied to the gate electrode 32 from the gate pad 13 through the gate wiring 14, the wiring layer 82, and the contact portions 75. When a voltage greater than a threshold is applied to the gate electrode 32, an inversion layer is formed in the base region 22, and the transistor is turned on. That is, an on-current flows from the drain electrode 11 to the source electrode 12 through the drain region 28, the drift region 21, the base region 22, the source region 23, the contact portions 71, and the wiring layer 81. When the voltage of the gate pad 13 is lowered and the voltage of the gate electrode 32 becomes equal to or less than the threshold (for example, 0V or less), the transistor is turned off, and the on-current does not flow.

As shown in FIG. 3, in the element region RC, the base region 22 is above the lower end of the gate electrode 32. In the element region RC, the lower surfaces of the gate insulating portions 42 are in contact with the drift region 21. In the element region RC, the gate electrode 32 faces the drain electrode 11 with the gate insulating portions 42 and the drift region 21 in between. A parasitic capacitance is generated between the gate electrode 32 and the drain electrode 11.

On the other hand, in the termination region RE, the gate electrode 32 is positioned above a part of the termination base region 24. That is, the termination base region 24 is formed below the gate trenches TR2. By interposing the termination base region 24 electrically connected to the source electrode 12, between the gate electrode 32 and the drain electrode 11, the parasitic capacitance between the gate electrode 32 and the drain electrode 11 can be reduced.

Further, by electrically connecting the termination base region 24 to the source electrode 12, an increase in the electric potential of the termination base region 24 with respect to the source electrode 12 can be suppressed, for example, when a surge occurs from the drain electrode 11. The application of a large voltage to the gate insulating portions 42 in contact with the termination base region 24 is suppressed, and destruction can be prevented. According to the embodiments, the characteristics in the termination region RE can be improved, such as the reduction of parasitic capacitance or the suppression of dielectric breakdown.

For example, when the impurity concentration of the second conductivity type in the termination base region 24 increases, the resistivity of the termination base region 24 decreases, and the increase in the electric potential of the termination base region 24 can be further suppressed. For example, the impurity concentration of the second conductivity type in the termination base region 24 may be higher than the impurity concentration of the second conductivity type in the base region 22.

For example, as shown in FIG. 3, the termination base region 24 may be shallower than the FP trenches TR1. That is, the lower end 24e of the termination base region 24 is above the lower ends 31e of the FP electrodes 31. Even in the termination region RE, the FP electrodes 31 face the drift region 21 in the X direction. Even when the termination base region 24 deeper than the base region 22 is provided, the reduction in breakdown voltage can be suppressed.

As shown in FIG. 3, the length L1 may be shorter than the length L2. The length L1 is the length in the Z direction of the termination base region 24, i.e., the length in the Z direction from the upper ends 31f of the FP electrodes 31 to the lower end 24e of the termination base region 24. The length L2 is the length in the Z direction from the lower end 24e of the termination base region 24 to the lower ends of the FP insulating portions 41.

As shown in FIG. 3, the length L3 may be shorter than the length L4. The length L3 is the length in the Z direction from the lower ends 42e of the gate insulating portions 42 to the lower end 24e of the termination base region 24. The length L4 is the length in the Z direction from the upper surface 20U of the semiconductor layer 20 to the lower ends 42e of the gate insulating portions 42. The length L3 may be longer than the thickness of the gate insulating portions 42.

As shown in FIG. 2, the gate electrode 32 has an end (electrode end 32f) in the X direction in the termination region RE. The electrode end 32f faces the termination base region 24 in the X direction, with the gate insulating portions 42 in between. In this way, the termination base region 24 covers the end face in the X direction of the gate trenches TR2 and surrounds the gate electrode 32. As a result, for example, the parasitic capacitance can be further reduced.

For example, the length L5 shown in FIG. 2 may be shorter than the period PX in which the FP electrodes 31 are arranged in the X direction. The length L5 is the distance in the X direction between an end 24f of the termination base region 24 that is contacting the base region 25, and the electrode end 32f of the gate electrode 32. By ensuring that the length L5 is not too long, the influence of the termination base region 24 on the breakdown voltage of the termination region RE can be suppressed.

Some FP electrodes 31 are arranged on the termination side relative to the end 24f of the termination base region 24. In other words, the position of the end 24f in the X direction is between the position of some FP electrodes 31 in the X direction and the element region RC.

As shown in FIG. 2 and FIG. 4, the semiconductor layer 20 has a base region 25 of the second conductivity type in the termination region RE, adjacent to the termination base region 24 in the X direction. The base region 25 is continuous from the end 24f of the termination base region 24. That is, the termination base region 24 is between the base region 25 and the element region RC in the X direction. As shown in FIG. 4, the base region 25 is provided on the drift region 21. The base region 25 is shallower than the termination base region 24. That is, the lower end of the termination base region 24 is below the lower end of the base region 25.

The impurity concentration of the second conductivity type in the termination base region 24 may be higher than the impurity concentration of the second conductivity type in the base region 25. The depth and impurity concentration of the base region 25 may be the same as the depth and impurity concentration of the base region 22. For example, the base region 22 and the base region 25 may be formed by the same ion implantation process. The breakdown voltage in the termination region RE can be adjusted by the base region 25. For example, by arranging the termination base region 24 closer to the element region RC than the base region 25 is, the influence of the termination base region 24 on the breakdown voltage of the termination region RE can be suppressed.

In the example of FIG. 4, the length L5 is longer than the length L6. The length L6 is the length of the base region 25 in the X direction, i.e., the distance in the X direction between the end 25f of the base region 25 and the end 24f of the termination base region 24.

As shown in FIG. 2, the first extending portions 32a of the gate electrode 32 include an outermost first extending portion 32A, with respect to the element region RC. The outermost extending portion 32A is the first extending portion 32a furthest from the element region RC in the second direction among the plurality of first extending portions 32a.

The termination base region 24 has an inner region 24A, also referred to herein as an “inner portion,” and an outer region 24B, also referred to herein as an “outer portion,” so as to sandwich the outermost extending portion 32A. In other words, the outermost extending portion 32A is positioned in the X direction between the inner region 24A and the outer region 24B. The inner region 24A is positioned in the X direction between the outer region 24B and the element region RC.

As shown in FIG. 2, the contact portions 71 connected to the semiconductor layer 20 are provided so as to surround the FP trenches TR1. The contact portions 71 may be electrically connected to the contact portions 72. For example, the contact portions 71 may be provided above the inner region 24A and not above the outer region 24B. The contact portions 71 are not provided outside the outermost extending portion 32A. For example, the entire upper end surface of the outer region 24B may be covered by the insulating layer 51 (see FIG. 3).

In the embodiments, the termination base region 24 is deeper than the gate trenches TR2. That is, a part of the termination base region 24 is provided below the gate trenches TR2. Therefore, the outer region 24B is integrated with the inner region 24A under the lower parts of the gate trenches TR2. The outer region 24B is electrically connected to the source electrode 12 through the inner region 24A and the contact portions 71 above the inner region 24A. As a result, even if there is no contact portion 71 above the outer region 24B, the rise in the electric potential rise the outer region 24B can be suppressed, and the destruction of the gate insulating portions 42 can be prevented.

As shown in FIG. 3, the inner region 24A of the termination base region 24 includes a first region (portion) 241 that does not overlap with the source electrode 12 in the Z direction and a second region (portion) 242 that overlaps with the source electrode 12 in the Z direction. The second region 242 is between the first region 241 and the element region RC. In this way, the termination base region 24 may be provided up to a position that is close to the element region RC and overlapping with the source electrode 12. The termination base region 24 covers a wide range of the gate trenches TR2. As a result, the parasitic capacitance can be further reduced.

As shown in FIG. 2, for example, the width W24 of the termination base region 24 in the X direction may be at least three times the period PX in which the FP electrodes 31 are arranged in the X direction. For example, the width W24B of the outer region 24B may be longer than the period PX. For example, the length L7 shown in FIG. 2 may be shorter than the period PX. The length L7 is the distance between the source region 23 and the termination base region 24.

According to the embodiments, a semiconductor device capable of improving the characteristics in the termination region RE can be provided.

In this specification, being “electrically connected” includes not only the case of being connected in direct contact, but also the case of being connected via another conductive member.

The relative high and low impurity concentrations between each semiconductor region in the embodiments described above can be confirmed using, for example, an SCM (Scanning Capacitance Microscope). The carrier concentration in each semiconductor region can be regarded as equal to the impurity concentration activated in each semiconductor region. Therefore, the relative high and low carrier concentrations between each semiconductor region can also be confirmed using an SCM. The relative high and low impurity concentrations between each semiconductor region can be regarded as corresponding to the relative high and low carrier concentrations between each semiconductor region. Furthermore, the impurity concentration in each semiconductor region can be measured using, for example, SIMS (Secondary Ion Mass Spectrometry).

While certain embodiments have been described, these embodiments have been presented by way of example only, and are not intended to limit the scope of the invention. Indeed, the novel embodiments described herein may be embodied in a variety of other forms; furthermore, various omissions, substitutions and changes in the form of the embodiments described herein may be made without departing from the spirit of the invention. The accompanying claims and their equivalents are intended to cover such forms or modifications as would fall within the scope and spirit of the invention. Additionally, the embodiments described above can be combined mutually.

What is claimed is:

1. A semiconductor device comprising:
a first electrode;
a second electrode positioned above the first electrode in a first direction; and
a semiconductor layer positioned in the first direction between the first electrode and the second electrode, including:
a first semiconductor region of a first conductivity type provided in both an inner area and an outer area of the semiconductor layer, wherein the outer area partially surrounds the inner area;
a second semiconductor region of a second conductivity type that is provided on the first semiconductor region in the inner area and that is electrically connected to the second electrode;
a third semiconductor region of the first conductivity type that is provided on the second semiconductor region;
a fourth semiconductor region of the second conductivity type that is provided on the first semiconductor region in the outer area and that is electrically connected to the second electrode;
a plurality of third electrodes provided in both the inner area and the outer area, wherein each of the plurality of third electrodes faces the first semiconductor region in a second direction perpendicular to the first direction, with a plurality of first insulating portions between the plurality of third electrodes and the first semiconductor region; and
a fourth electrode provided in both the inner area and the outer area,
wherein the fourth electrode extends between two of the plurality of third electrodes that are adjacent in the second direction,
wherein in the inner area, the fourth electrode is separated from the plurality of third electrodes by the semiconductor layer and a first group of second insulating portions,
wherein in the inner area, the fourth electrode faces the first semiconductor region, the second semiconductor region, and the third semiconductor region in the second direction with the first group of second insulating portions between the fourth electrode and the first semiconductor region, the second semiconductor region, and the third semiconductor region, and
wherein in the outer area, the fourth electrode is positioned above the fourth semiconductor region in the first direction with a second group of the second insulating portions between the fourth electrode and the fourth semiconductor region.

2. The semiconductor device according to claim 1, wherein a lower end of the fourth semiconductor region is above lower ends of the plurality of third electrodes in the first direction.

3. The semiconductor device according to claim 1, wherein the concentration of a second conductivity type impurity in the fourth semiconductor region is higher than the concentration of the second conductivity type impurity in the second semiconductor region.

4. The semiconductor device according to claim 1, wherein in the outer area, the fourth electrode faces the fourth semiconductor region in the second direction with the second group of the second insulating portions between the fourth electrode and the fourth semiconductor region.

5. The semiconductor device according to claim 1,
wherein the fourth semiconductor region includes an outer portion and an inner portion positioned in the second direction between the outer portion and the inner area of the semiconductor layer, and
wherein the fourth electrode includes a plurality of first extending portions extending in a third direction perpendicular to both the first and second directions, the first extending portions further extending between the two of the plurality of third electrodes that are adjacent in the second direction.

6. The semiconductor device according to claim 5, wherein an outermost one of the first extending portions in the second direction, is positioned in the second direction between the outer portion and the inner portion.

7. The semiconductor device according to claim 6,
wherein a plurality of contacts coupled to the semiconductor layer are provided above the inner portion in the first direction, and
wherein the fourth semiconductor region is electrically connected to the second electrode via the contacts.

8. The semiconductor device according to claim 5, wherein a plurality of contacts coupled to the semiconductor layer are provided above the inner portion in the first direction.

9. The semiconductor device according to claim 8, wherein the fourth semiconductor region is electrically connected to the second electrode via the contacts.

10. The semiconductor device according to claim 8, wherein the contacts include at least one metal material selected from the group consisting of titanium, titanium nitride, tungsten, copper, and aluminum.

11. The semiconductor device according to claim 1, wherein the semiconductor layer includes a fifth semiconductor region of the second conductivity type in the outer area, adjacent to the fourth semiconductor region in the second direction.

12. The semiconductor device according to claim 11, wherein a lower end of the fourth semiconductor region is below a lower end of the fifth semiconductor region in the first direction.

13. The semiconductor device according to claim 11, wherein the fourth semiconductor region is positioned in the second direction between the fifth semiconductor region and the inner area.

14. The semiconductor device according to claim 11, wherein a length in the second direction between the fourth electrode and an end of the fourth semiconductor region that is contacting the fifth semiconductor region, is longer than a length of the fifth semiconductor region in the second direction.

15. The semiconductor device according to claim 1,
wherein the fourth semiconductor region includes a first portion and a second portion positioned in the second direction between the first portion and the inner area, and
wherein the second portion overlaps with the second electrode in the first direction.

16. The semiconductor device according to claim 15, wherein the first portion does not overlap with the second electrode in the first direction.

17. The semiconductor device according to claim 1, wherein a length of the fourth semiconductor region in the first direction is shorter than a length from lower ends of the first insulating portions to a lower end of the fourth semiconductor region in the first direction.

18. The semiconductor device according to claim 1, wherein the plurality of third electrodes are electrically connected to the second electrode.

19. The semiconductor device according to claim 1, further comprising:
a gate pad provided in the outer area,
wherein the gate pad is electrically connected to the fourth electrode.

20. A semiconductor device comprising:
a first electrode;
a second electrode positioned above the first electrode in a first direction; and
a semiconductor layer positioned in the first direction between the first electrode and the second electrode, including:
a first semiconductor region of a first conductivity type provided in both an inner area and an outer area of the semiconductor layer, wherein the outer area partially surrounds the inner area;
a second semiconductor region of a second conductivity type that is provided on the first semiconductor region in the inner area and that is electrically connected to the second electrode;
a third semiconductor region of the first conductivity type that is provided on the second semiconductor region;
a fourth semiconductor region of the second conductivity type that is provided on the first semiconductor region in the outer area and that is electrically connected to the second electrode;
a plurality of third electrodes provided in both the inner area and the outer area, wherein each of the plurality of third electrodes faces the first semiconductor region in a second direction perpendicular to the first direction, with a plurality of first insulating portions between the plurality of third electrodes and the first semiconductor region; and
a fourth electrode provided in both the inner area and the outer area,
wherein the fourth electrode extends between two of the plurality of third electrodes that are adjacent in the second direction,
wherein in the inner area, the fourth electrode is separated from the plurality of third electrodes by the semiconductor layer and a first group of second insulating portions,
wherein in the inner area, the fourth electrode faces the first semiconductor region, the second semiconductor region, and the third semiconductor region in the second direction with the first group of second insulating portions between the fourth electrode and the first semiconductor region, the second semiconductor region, and the third semiconductor region,
wherein in the outer area, the fourth electrode is positioned above the fourth semiconductor region in the first direction with a second group of the second insulating portions between the fourth electrode and the fourth semiconductor region,
wherein the concentration of a second conductivity type impurity in the fourth semiconductor region is higher than the concentration of the second conductivity type impurity in the second semiconductor region,
wherein the fourth semiconductor region includes an outer portion and an inner portion positioned in the second direction between the outer portion and the inner area of the semiconductor layer,
wherein the fourth electrode includes a plurality of first extending portions extending in a third direction perpendicular to both the first and second directions, the first extending portions further extending between the two of the plurality of third electrodes that are adjacent in the second direction, and
wherein an outermost one of the first extending portions in the second direction, is positioned in the second direction between the outer portion and the inner portion.
